(19) United States
(12) Patent Application Publication
(10) Pub. No.: US 2020/0059153 A1
(43) Pub. Date: Feb. 20, 2020

(54) POWER SUPPLY SYSTEM FOR VENTILATION FAN

(71) Applicant: Dacs A/S, Nørre Snede (DK)

(72) Inventor: Jens Dybdahl, Ejstrupholm (DK)

(21) Appl. No.: 16/611,116

(22) PCT Filed: May 3, 2018
(86) PCT No.: PCT/EP2018/061284

§ 371 Date: Nov. 5, 2019

(30) Foreign Application Priority Data
May 8, 2017 (DK) PA201770322

(51) Int. Cl. H02M 1/10; H02J 7/35; H02P 1/00; H02P 27/06; H05K 7/20; H02M 7/797

(52) U.S. Cl. CPC H02M 1/10; H02J 7/35; H02P 1/00; F24F 2005/0067; H05K 7/20209; H02M 7/797; H02P 2207/05; H02P 27/06

(57) ABSTRACT

A power supply system is disclosed for powering the operation of a ventilation fan driven by a permanent magnet motor, the supply system having an electric converter comprising a first input terminal for receiving an input of alternating 5 current (AC), a second input terminal for receiving an input of direct current (DC) and an output terminal for providing an output for powering the operation of the permanent magnet motor, wherein said supply system is configured for providing said output from said input of alternating current (AC) as well as from said input of direct current (DC). Further is a ventilation system disclosed comprising a plurality of ventilation fans each comprising a permanent magnet motor which each is connected to such power supply system.

The present invention relates to a power supply system for ventilation fans driven by permanent magnet motors, to ventilation fans having such power supply systems as well as to a ventilation system comprising a plurality of such ventilation fans.

### BACKGROUND

It is well known in the art to utilise permanent magnet motors as drivers to ventilation fans, such as axial flow fans for ventilation of e.g. animal stable.

### DESCRIPTION OF THE INVENTION

The present invention relates in a first aspect to a power supply system for powering the operation of a ventilation fan driven by a permanent magnet motor, the power supply system having an electric converter comprising a first input terminal for receiving an input of alternating current (AC), a second input terminal for receiving an input of direct current (DC) and an output terminal for providing an output for powering the operation of the permanent magnet motor, wherein said supply system is configured for providing said output from said input of alternating current (AC) as well as from said input of direct current (DC).

The ventilation fan is in particular an axial flow fan well known in the art, such as the one disclosed in WO 2015/090318.

The power supply system of the present invention is configured for receiving a power input from an AC source as well as from a DC source an utilise both for generating the power output for supplying to a permanent magnet motor of a ventilation fan.

In particular, the power supply system may be configured for providing said output from said input of alternating current (AC) alone, from said input of direct current (DC) alone as well as from a combination of said input of alternating current (AC) and said input of direct current (DC). Thus, the power supply may operate to powering the permanent magnet motor in each of the three situations that the power supply system is provided with an AC power input at the first terminal only, with a DC power input at the second terminal only and with an AC power input at the first terminal as well as with a DC power input at the second terminal, in which latter case the power supply system may utilise both power inputs to generate the power output to the permanent magnet motor at the output terminal.

Thus, the power supply system according to the present invention is highly flexible with regard to the power input it receives and to variations in the power input, which may occur in case the DC power input at the second terminal of the power supply system is provided by means of photovoltaic elements and/or a rechargeable electric battery, and it is particularly flexible in the embodiment of the power supply system that may operate with a mixture of an AC power input at the first terminal and with a DC power input at the second terminal.

The output of the power supply system at the output terminal to the permanent magnet motor is preferably an alternating current output, which is suitable for driving a Permanent Magnet Synchronous Motor (PMSM), the rotational speed of which is controlled by the frequency of the power output from the power supply system, for which reason the power supply system may be configured for providing the output at a variable frequency, which may be controlled so as to determine the rotational speed of the ventilation fan.

The power supply system of the present invention may in a preferred embodiment comprise a rectifier part for rectifying said input of alternating current (AC) to a direct current (DC) for a direct current link part of said power supply system, and said second input terminal may be connected to said direct current link part.

The second input terminal is preferably connected directly to the two conductors of the direct current link part, i.e. the positive conductor and the negative conductor of the direct current link. The direct current link part typically comprises a capacitor connecting the two conductors of the direct current link part. By connecting the DC source directly to the direct current link part of the power supply system, an inexpensive solution is reached for the utilisation of direct current power sources, such as photovoltaic elements in an AC driven system as the DC-AC conversion which incorporates power losses and a costly converter may be omitted.

The power supply system may further comprise a power inverter part for converting electric power from said direct current link part to alternating current for providing said output of the power supply system, i.e. constituting an AC-DC-AC converter. The power inverter part is configured for providing a three-phase alternating current (AC) for the permanent magnet motor.

The power supply system may further comprise a power factor correction (PFC) part. The power factor correction (PFC) part is preferably an active PFC for compensating for an input of alternating current having a power factor deviating from 1 and is preferably also compensating for contents of higher harmonics of the basic sine wave of the input of alternating current. The active PFC part may be of the boost type, of the buck type or of the buck/boost type, all of which are well known in the art.

The present invention relates in a second aspect to a ventilation fan comprising a permanent magnet motor and a power supply system according to the first aspect of the present invention. The ventilation fan may in particular be an axial flow fan well known in the art, such as the one disclosed in WO 2015/090318. The rotor diameter of the ventilation fan is preferably in the range of 40 to 200 cm, such as in the range of 50 to 150 cm. The permanent magnet motor will typically have an output in the range of 0.5 to 2.5 kW, such as in the range of 0.75 to 1.5 kw. The variable rotational speed of the motor is preferably from an idle state and to 500-800 rotations per minute in a direct drive arrangement of the fan.

The permanent magnet motor of the ventilation fan is preferably a synchronous motor, a Permanent Magnet Synchronous Motor (PMSM) which is fed an alternating current from the power supply system, the frequency of which controls the rotational speed of the motor.

In a third aspect, the present invention relates to a ventilation system comprising a plurality of ventilation fans each comprising a permanent magnet motor which each is connected to a power supply system according to the first aspect of the present invention. The ventilation fans may in particular be axial flow fans well known in the art, such as the one disclosed in WO 2015/090318. The rotor diameter of the ventilation fans are preferably in the range of 40 to 200 cm, such as in the range of 50 to 150 cm. The permanent magnet motor will typically have an output in the range of 0.5 to 2.5 kW, such as in the range of 0.75 to 1.5 kw. The variable rotational speed of the motor is preferably from an idle state and to 500-800 rotations per minute in a direct drive arrangement of the fan.

The permanent magnet motors are preferably synchronous motors, Permanent Magnet Synchronous Motors (PMSM) which each are fed an alternating current from the power supply system, the frequency of which controls the rotational speed of the motor.

The ventilation system may further comprise a direct current power source, which is arranged to provide said input of direct current (DC) to the plurality of power supply systems of the ventilation system. The direct current power source may comprise a plurality of photovoltaic elements and/or a rechargeable electric battery, which may be arranged for being charged by means of surplus electric power generated by the photovoltaic elements. The direct current power source may alternatively or additionally comprise a thermoelectric generator, also known as a Seebeck generator, which utilises the thermoelectric effect to generate an electric power from a thermal gradient, and which also may be employed to charge the rechargeable electric battery.

In a preferred embodiment, the direct current power source of the ventilation system comprises a direct current to direct current (DC-to-DC) converter for providing a direct current of substantially constant voltage to said plurality of power supply systems of the ventilation system.

1. A power supply system configured to power operation of a ventilation fan driven by a permanent magnet motor, the power supply system comprising an electric converter, which comprises a first input terminal configured to receive an input of alternating current (AC), a second input terminal configured to receive an input of direct current (DC) and an output terminal configured to provide an output, which powers operation of the permanent magnet motor, wherein said power supply system is further configured to provide said output from said input of alternating current (AC) as well as from said input of direct current (DC).

2-15. (canceled)

16. The power supply system according to claim 1, wherein said power supply system is configured to provide said output from said input of alternating current (AC) alone, from said input of direct current (DC) alone as well as from a combination of said input of alternating current (AC) and said input of direct current (DC).

17. The power supply according to claim 1, wherein said output is an alternating current output.

18. The power supply system according to claim 1, comprising a rectifier part configured to rectify said input of alternating current (AC) to a direct current (DC) for a direct current link part of said supply system, and wherein said second input terminal is connected to said direct current link part.

19. The power supply system according to claim 18, further comprising a power inverter part configured to convert electric power from said direct current link part to alternating current so as to provide said output of the power supply system.

20. The power supply system according to claim 19, wherein said power inverter part is configured to provide a three-phase alternating current (AC) for the permanent magnet motor.

21. The power supply system according to claim 18, wherein the power supply system further comprises a power factor correction (PFC) part.

22. A ventilation fan comprising a permanent magnet motor and a power supply system according to claim 1.

23. The ventilation fan according to claim 22, wherein the permanent magnet motor is a synchronous motor.

24. A ventilation system comprising a plurality of ventilation fans each comprising a permanent magnet motor connected to a power supply system according to claim 1.

25. The ventilation system according to claim 24, wherein the permanent magnet motors of said plurality of ventilation fans are synchronous motors (PMSM).

26. The ventilation system according to claim 24, wherein the system further comprises a direct current power source, which is configured to provide said input of direct current (DC) to the plurality of power supply systems of the ventilation system.

27. The ventilation system according to claim 26, wherein the direct current power source comprises a plurality of photovoltaic elements.

28. The ventilation system according to claim 26, wherein the direct current power source comprises a rechargeable electric battery.

29. The ventilation system according to claim 26, wherein the direct current power source comprises a direct current to direct current (DC-to-DC) converter configured to provide a direct current of substantially constant voltage to said plurality of power supply systems of the ventilation system.
